(19) United States
(12) Patent Application Publication
(10) Pub. No.: US 2024/0324289 A1
(43) Pub. Date: Sep. 26, 2024

(54) DISPLAY DEVICE

(71) Applicant: LG Display Co., Ltd., Seoul (KR)

(72) Inventors: Jae-Sung PARK, Paju-si (KR); Soo-Hong CHOI, Paju-si (KR); Hong-Jae SHIN, Paju-si (KR)

(21) Appl. No.: 18/586,256

(22) Filed: Feb. 23, 2024

(30) Foreign Application Priority Data
Mar. 24, 2023 (KR) 10-2023-0038488

(51) Int. Cl. H10K 59/121; H10K 59/122; H10K 59/123; H10K 59/126; H10K 59/131

(52) U.S. Cl. CPC H10K 59/1213; H10K 59/122; H10K 59/123; H10K 59/126; H10K 59/1315

(57) ABSTRACT

The present disclosure relates to a display device that includes a substrate including a display area and a non-display area including at least one trench area. The display device includes plural sub-pixels disposed in the display area, a driving circuit and a power line disposed in the non-display area, at least one transistor disposed in the plural sub-pixels, an overcoat layer disposed on the at least one transistor and a light emitting diode. The light emitting diode includes a first electrode and a second electrode disposed on the first electrode. The light emitting diode is disposed on the overcoat layer and linked electrically to the at least one transistor. The overcoat layer and the second electrode extends to the non-display area. The second electrode is linked to a portion of an auxiliary electrode in the at least one trench area.

### CROSS-REFERENCE TO RELATED APPLICATIONS

This application claims the benefit of and the priority of Korean Patent Application No. 10-2023-0038488, filed in the Republic of Korea on Mar. 24, 2023, which is expressly incorporated hereby in its entirety into the present application.

### BACKGROUND

### Technical Field

The present disclosure relates to a display device, and more particularly, a display device with improved reliability through a space arrangement of a non-display area.

### Description of the Related Art

A light emitting display device is a self-emitting display device not requiring a separate light source, unlike a liquid crystal display device, and therefore, can be manufactured in a lightweight and thin form. Also, the light emitting display devices are not only advantageous in terms of power consumption due to low voltage operation, but also have beneficial color reproduction, response speed, viewing angle, and contrast ratio (CR), so the light emitting display devices are expected to be used in various fields.

The display device includes a display panel having plural data lines and plural gate lines, a data driving circuit that outputs data signals through the plural data lines, and a driving panel circuit that outputs gate signals through the plural gate lines. In such organic light emitting display devices, there is a disadvantage in that the light-emitting properties of the light emitting diodes are deteriorated due to external moisture in the light emitting diodes that extends to the non-display area, and thereby deteriorating the display quality of the image in the device.

### BRIEF SUMMARY

An aspect of the present disclosure provides a display device where a trench area and a power line disposed in a non-display area are arranged optimally so that amount of external moisture infiltrated to a light emitting diode can be reduced or minimized.

Another aspect of the present disclosure provides a display device where a second electrode is connected to an auxiliary electrode in the non-display area so that the second electrode extended to the non-display area has lower electrical resistance.

Another aspect of the present disclosure provides a display device into which external moisture cannot be infiltrated by connecting the second electrode to the auxiliary electrode in the trench area.

Additional features and aspects will be set forth in the description that follows, and in part will be apparent from the description, or may be learned by practice of the disclosed concepts provided herein. Other features and aspects of the disclosed concept may be realized and attained by the structure particularly pointed out in the written description, or derivable therefrom, and the claims hereof as well as the appended drawings.

To achieve these and other advantages and in accordance with objects of the disclosure, as embodied and broadly described herein, in one aspect, the present disclosure provides a display device includes a substrate including a display area and a non-display area. The display device includes plural sub-pixels disposed in the display area; a driving circuit and a power line disposed in the non-display area; at least one transistor disposed in the plural sub-pixels; an overcoat layer disposed on the at least one transistor; and light emitting diode disposed on the overcoat layer. The light emitting diode including a first electrode electrically linked to the at least one transistor, a second electrode facing the first electrode and an emissive layer disposed between the first electrode and the second electrode. The overcoat layer and the second electrode extend to the non-display area. At least a portion of the second electrode is linked, namely is electrically connected to an auxiliary electrode in at least one trench area disposed in the non-display area.

The at least one trench area can be disposed between the driving circuit and the power line.

The display device can further comprise a bank layer disposed on the overcoat layer and overlapped to a portion of the first electrode in the display area, wherein the bank layer is extended to and disposed in the non-display area.

The display device can further comprise a connection line extended in a row direction disposed in the at least one trench area, and wherein the link line is arranged parallel to a gate line in the display area.

The connection line can be a gate low-potential voltage connection line and can connect the driving circuit to the power line, and the power line can be a gate low-potential voltage line.

The display device can further comprise at least one dam disposed in the at least one trench area.

The overcoat layer and the bank layer can constitute the at least one dam.

At least a portion of the auxiliary electrode can be disposed between the overcoat layer and the bank layer.

The second electrode can be connected to the auxiliary electrode among the at least one dam.

The auxiliary electrode can comprise a same material as the first electrode in the display area.

The bank layer can be disposed on the overcoat layer.

The bank layer can be disposed on and at least one side of the overcoat layer.

The display device can further comprise a light shield layer disposed under the at least one transistor.

The power line can comprise a same material as the light shield layer.

The power line can be disposed in a same layer as the light shield layer.

A side of the at least one trench area can have a straight line in a plan view.

A side of the at least one trench can have a concavo-convex shape in a plan view.

The emissive layer can comprise an organic luminescent material.

The emissive layer can comprise inorganic luminescent particles.

The amount of external moisture infiltrated to the light emitting diode can be reduced or minimized by arranging maximally the trench area and the power line in the non-display area. The second electrode is connected to the auxiliary electrode in the non-display area so that the second electrode can have lower electrical resistance. The second electrode is connected to the auxiliary electrode in the trench area so as to reduce or minimize the external moisture from infiltrating to the diode.

In addition, the trench using the overcoat layer and the bank layer in the non-display are arranged so that the amount of the external moisture filtrating into the display area can be reduced or minimized. Accordingly, it is possible to prevent the properties of the light emitting diode and the quality of the images from lowering.

It is to be understood that both the foregoing general description and the following detailed description are merely by way of example and are intended to provide further explanation of the inventive concepts.

### BRIEF DESCRIPTION OF THE SEVERAL VIEWS OF THE DRAWINGS

The accompanying drawings, which are included to provide a further understanding of the disclosure, are incorporated in and constitute a portion of this application, illustrate embodiments of the disclosure and together with the description serve to explain principles of the disclosure.

FIG. 1 illustrates a display device in accordance with one embodiment of the present disclosure.

FIG. 2 illustrates a sub-pixel circuit diagram of a display device in accordance with one embodiment of the present disclosure.

FIG. 3 illustrates a schematic cross-sectional view of a display device in accordance with one embodiment of the present disclosure.

FIG. 4 illustrates a schematic diagram of a gate driving panel circuit and components of a non-display area in accordance with one embodiment of the present disclosure.

FIG. 5 illustrates a plan view enlarging a portion of FIG. 4.

FIG. 6 illustrate a cross-sectional view taken along a line VI-VI′ of FIG. 4.

### DETAILED DESCRIPTION

The advantages and features of the present disclosure, and methods for achieving those advantages and feature will become clear by referring to the embodiments described in detail below along with the accompanying figures. However, the present disclosure is not limited to the embodiments described below, but will be implemented in various different forms, and the embodiments only serve to ensure that the present disclosure is complete and to fully inform those skilled in the art.

The shape, size, dimension (e.g., length, width, height, thickness, radius, diameter, area, etc.), ratio, and number of elements and the likes disclosed in the figures for describing the embodiments of the present disclosure are illustrative, and the present disclosure is not limited to the matters shown.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Identical reference numerals refer to the same elements throughout the specification. Additionally, in describing the present disclosure, if it is determined that a detailed description of related known technology may unnecessarily obscure the present disclosure, the detailed description will be omitted.

When the term “includes,” “has,” “comprises” in the specification are used, other part can be added unless “only” is used. When an element or a component is expressed in the singular, plural elements or components are included unless specifically stated otherwise.

When interpreting an element or a component, it is interpreted to include the margin of error even if there is no explicit description.

In case of a description of a positional relationship, for example, if the positional relationship of two element is described as “on,” “over,” “under,” “bottom,” “side,” “next” and the likes, one or more other elements can be placed between two elements unless “immediately” or “directly” is used.

Although first, second and the likes are used to describe various components, those components are not limited by these terms. These terms are merely used to distinguish one component from another. Accordingly, the first component described below may be the second component within the technical idea of the present disclosure. Each feature of various embodiment of the present disclosure can be combined with each other, particularly or entirely, and various technological interconnections and operations are possible, and each embodiment may be implemented independently of each other or together in an associated relationship.

Reference will now be made in detail to aspects of the disclosure, examples of which are illustrated in the accompanying drawings. Wherever possible, the same reference numbers will be used throughout the drawings to refer to the same or like parts.

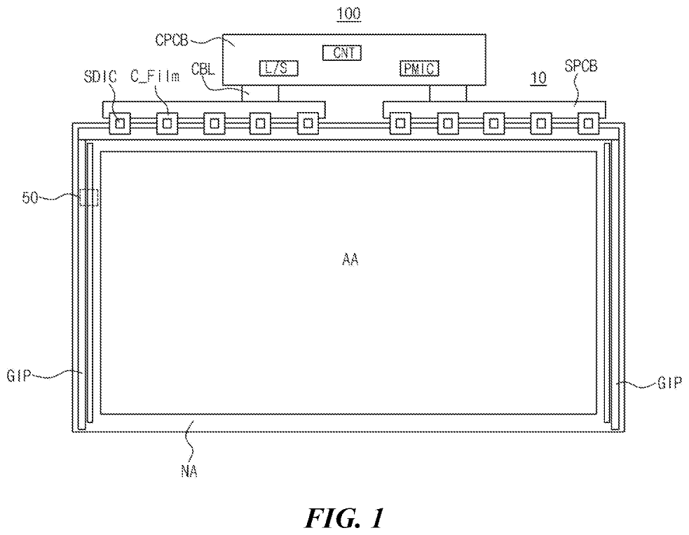

FIG. 1 illustrates a display device in accordance with one embodiment of the present disclosure.

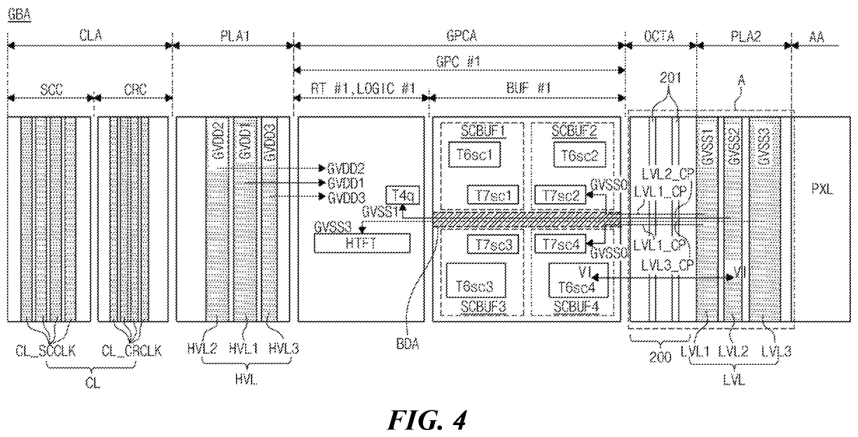

As illustrated in FIG. 1, a display device 10 can include plural areas. For example, the display device 100 comprises at least one display area AA where an image is displayed in a display panel 10. The display area AA includes plural pixels PXL (FIG. 4) therein. The display device 100 can comprise a non-display area NA disposed at least one side of the display area AA.

The at least one non-display area NA where no image is displayed can include a driving circuit and power lines and can be disposed at least one side of the display area AA.

With referring to FIG. 1, the non-display area NA surrounds the rectangular display area AA and disposed outside of the display area AA. However, it is understood that the shapes of the display area AA and the arrangements of the non-display area NA disposed adjacently to the display area AA are not limited to the example display device 100 shown in FIG. 1. Such a non-limiting example of the shapes can include a pentagon, a hexagon, a circle, an ellipse and the likes, but is not limited thereto.

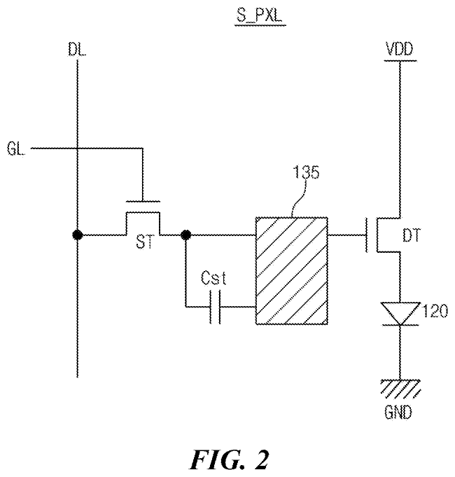

Each of the pixels PXL (FIG. 4) in the display area AA includes sub-pixels S_PXL (FIG. 2). Sub-pixel S-PXL can display red color I, green color (G), blue color (G), white color (W) and the likes. In addition, each of the pixel PXL (FIG. 4) and/or the sub-pixels S_PXL can be associated with a pixel circuit including at least one transistor disposed on a substrate of the display device 100. Each of the pixel circuits can be electrically connected to at least one driving circuit, for example, a gate driving panel circuit GIP disposed in the non-display area NA, a gate line GL (FIG. 2) and a data line DL (FIG. 2) for communication with a data driver such as source driver integrated circuit SDIC.

The at least one driving circuit can be implemented by transistors disposed in the non-display area NA as illustrated in FIG. 1. A clock line, the gate driving panel circuit GIP and a gate power line can be disposed within the non-display area NA. The gate power line can include a gate high-potential power voltage line and a gate low-potential power voltage line.

The gate driving panel circuit GIP can be implemented by using plural transistors and plural connection lines disposed on the substrate. Non-limiting examples of the circuits that can be implemented the transistors on the substrate can include inverter circuit, multiplexer, electro static discharge (ESD) circuit, and the likes, but is not limited thereto.

Some driving circuits can be provided as an integrated circuit (IC) chips and/or can be mounted within the non-display area NA of the display panel 10 by using chip-on-glass (COG), chip-on-plastic (COP) or other similar processes. Also, other driving circuits can be mounted on another substrate and/or can be coupled to a connection interface such as pads/bumps, and fins by using a printed circuit such as a flexible printed circuit board (FPCB), chip-on-film (COF), tape-carrier-package (TCP) and/or other proper technologies.

The driving circuit such as the gate driving panel circuit GIP can include a gate drive integrated circuit within the display panel 10 so as to lower production cost owing to reduction of the number of the integrated circuit and to provide high-speed scan signal to the display area AA in the display panel 10.

With referring to FIG. 1, a low-potential voltage, a touch signal and a gate control signal (GCS) each of which is output from a flexible printed circuit board (FPCB) can be applied to the display panel 10, and a high-potential voltage can be applied to the display panel 10 through a data driver.

The data driving circuit can include plural source driver integrated circuits SDIC and can be implemented by chip-on-film (COF) process. Each of the plural source driver integrated circuits SDIC can be mounted on a circuit film C_Film that is linked to the non-display area NA of the display panel 10. The circuit film C_Film can be referred as a flexible printed circuit (FPC).

The display device 100 can include at least one source printed circuit board SPCB for circuit connections among the plural source driver integrated circuits SDIC and other components such as a controller CNT, a level shifter L/S, a power management integrated circuit PMIC, and the likes. The display device 100 can include a control printed circuit board CPCB for mounting control components and various electric components. The circuit film C_Film on which the source driver integrated circuit SDIC can be connected to the at least one source printed circuit board SPCB. In other words, one side of the circuit film C_Film on which the source driver integrated circuit SDIC can be electrically connected to the display panel 10 and another side of the circuit film C_Film can be electrically connected to the source printed circuit board SPCB.

The controller CNT and the power management integrated circuit PMIC can be mounted on the control printed circuit board CPCB.

The controller CNT can perform general control functions with regard to the driving of the display panel 10. As an example, the controller CNT can control of the operations of the plural source driver integrated circuits SDIC and/or the gate driving panel circuit GIP.

The power management integrated circuit PMIC can control various voltages or currents. As an example, the power management integrated circuit PMIC can control voltages or currents that provide or will provide to the plural source driver integrated circuits SDIC and the gate driving panel circuit GIP.

In one embodiment, the at least one source printed circuit board SPCB can be connected in a circuit to the control printed circuit board CPCB through at least one connection cable CBL. As an example, the connection cable CBL can be one of a flexible printed circuit (FPC) and a flexible flat cable (FFC), and the likes.

In another embodiment, the at least one source printed circuit board SPCB and the control printed circuit board CPCB can be integrated to one print circuit board.

The display device 100 can further include a level shifter L/S for adjusting a voltage level of signals. For example, the level shifter L/S can be disposed in the control print circuit board CPCB or the source print circuit board SPCB.

FIG. 2 illustrates a sub-pixel circuit diagram of a display device in accordance with one embodiment of the present disclosure.

With referring to FIG. 2, the sub-pixel S_PXL of the display device 100 in accordance with the present disclosure can include a switching thin film transistor ST, a driving thin film transistor DT, a compensation circuit 135 and a light emitting diode 120.

The light emitting diode 120 can be operated to emit light by a driving current generated by the driving thin film transistor DT. The switching thin film transistor ST can perform switching operation so that the data signal supplied via the data line DL can be stored as a data voltage in a capacitor Cst in response to the gate signal suppled via the gate line GL. The driving thin film transistor DT can operate so that constant driving current flows between a high-potential power line VDD and a low-potential power line GND in response to the data voltage stored in the capacitor Cst.

The sub-pixel S_PXL in FIG. 2 constitutes two transistors ST and DT (2T) and one capacitor Cst (1C) structure including the switching thin film transistor ST, the driving thin film transistor DT, the capacitor Cst and the light emitting diode 120. However, the sub-pixel S_PXL can have various structures such as a 3T1C structure (three transistors and one capacitor), a 4T2C structure (four transistors and two capacitors), a 5T2C structure (five transistors and two capacitors), a 6T1C structure (six transistors and one capacitor), a 6T2C structure (six transistors and two capacitors), a 7T1C structure (seven transistors and one capacitor), a 7T2C structure (seven transistors and two capacitors), and the likes.

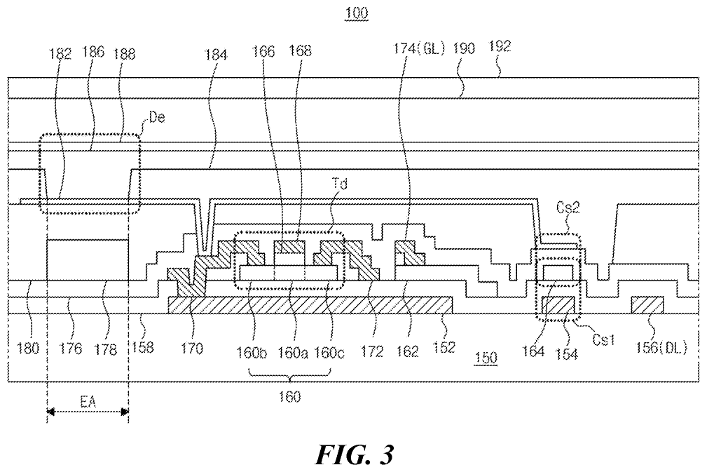

FIG. 3 illustrates a schematic cross-sectional view of one sub-pixel in a display device in accordance with one embodiment of the present disclosure.

As illustrated in FIG. 3, each of the sub-pixels S_PXLs (FIG. 2) in the display device 100 in accordance with one embodiment of the present disclosure can a substrate 150, a driving thin film transistor Td and a light emitting diode De. A light shield layer 152, a first capacitor pattern 154 and a data line 156 (DL) can be disposed on the substrate 150.

In one embodiment, the substrate 150 can include a glass or multi layers that an organic layer and an inorganic layer are alternatively disposed. In another embodiment, the substrate 150 can include multi layers that an organic insulating material such as polyimide and an inorganic insulating material such as silicon oxide SiOx (0<x≤2) are alternately disposed.

The light shield layer 152, the first capacitor pattern 154 and the data line 156 can be disposed in the same layer through one mask process, and/or can include the same material such as metal.

For example, each of the light shield layer 150, the first capacitor pattern 154 and the data line 156 can have a single-layered structure or a multi-layered structure comprising molybdenum (Mo), aluminum (Al), chromium (Cr), gold (Au), titanium (Ti), nickel (Ni), neodymium (Nd), copper (Cu) and/or alloys thereof, but is not limited thereto.

A buffer layer 158 is disposed on the light shield layer 152, the first capacitor pattern 154 and the data line 156 over entire surface of the substrate 150 for blocking external moisture from being infiltrated. The buffer layer 158 can include multi layers of silicon nitride (SiNx) and/or silicon oxide (SiOx) (0<x≤2).

An active layer 160 and a semiconductor layer 162 are disposed on the buffer layer 158 correspondingly to the light shield layer 152. A second capacitor pattern 164 is disposed on the buffer layer 158 correspondingly to the first capacitor pattern 154.

For example, the active layer 160, the semiconductor layer 162 and the second capacitor pattern 164 can be disposed in the same layer through one mask process, and/or can include the same material such as polycrystalline silicon and/or oxide semiconductor.

The active layer 160 can include a channel area 160a of center region, and a source region 160b and a drain region 160c of both side regions. The channel area 160a can include pure semiconductor material without doping with impurities, and the source area 160b and the drain area 160c can include semiconductor material doped with impurities.

The first capacitor pattern 154, the buffer layer 158 and the second capacitor pattern 164 can constitute a first storage capacitor Cs1.

A patterned gate insulating layer 166 is disposed on the channel area 160a, the source area 160b and the drain area 160c of the active layer 160 and the semiconductor layer 162. The gate insulating layer 166 can have a single-layered structure or a multi-layered structure of inorganic insulating material such as silicon oxide (SiOx) and/or silicon nitride (SiNx) (0<x≤2).

A gate electrode 168, a source electrode 170 and a drain electrode 172 are disposed on the gate insulating layer 166 correspondingly to the channel area 160a, the source area 160b and the drain area 160c of the active layer 160, respectively. A gate line 174 (GL) can be disposed on the gate insulating layer 166 correspondingly to the semiconductor layer 162.

As an example, the gate electrode 168, the source electrode 170, the drain electrode 172 and the gate line 174 can be disposed in the same layer through one mask process, and/or can include the same material such as metal.

For example, each of the gate electrode 168, the source electrode 170, the drain electrode 172 and the gate line 174 can have a single-layered structure or a multi-layered structure comprising molybdenum (Mo), aluminum (Al), chromium (Cr), gold (Au), titanium (Ti), nickel (Ni), neodymium (Nd), copper (Cu) and/or alloys thereof, but is not limited thereto.

The gate electrode 168 does not contact the channel area 160a of the active layer 160. The source electrode 170 contacts the light shield layer 152 through a contact hole of the buffer layer 158 and the source area 160b of the active layer 166 through a side of the gate insulating layer 166. The drain electrode 172 contacts the drain area 160c of the active layer 166 through another side of the gate insulating layer 166. The gate line 174 contacts the semiconductor layer 162 through a side of the gate insulating layer 166.

The active layer 160, the gate insulating layer 166, the gate electrode 168, the source electrode 170 and the drain electrode 172 constitute the driving thin film transistor Td.

An interlayer insulating layer 176 is disposed on the gate electrode 168, the source electrode 170, the drain electrode 172 and the gate line 174 over the entire surface of the substrate 150. The interlayer insulating layer 176 can have a single-layered structure or a multi-layered structure of an inorganic material such as silicon oxide (SiOx) and/or silicon nitride (SiNx) (0<x≤ 2).

A color filter layer 178 is disposed on the interlayer insulating layer 176 in an emitting area EA. The color filter layer 178 can be disposed correspondingly to a red sub-pixel region, a green sub-pixel region, a blue sub-pixel region and a white sub-pixel region by emission color of each sub-pixel S_PXL (FIG. 2).

In FIG. 3, the color filter layer disposed between the light emitting diode De and the substrate 150 in case that the display device 100 is a bottom-emission type. Alternatively, when the display device 100 is a top-emission type, the color filter layer 170 can be disposed on a second electrode 188. In certain embodiment, the color filter layer 178 can be omitted when the light emitting diode De emits red color, green color and/or blue color.

An overcoat layer 180 can be disposed on the color filter layer 178 over the entire surface of the substrate 150. In one embodiment, the overcoat layer 180 can include an organic insulating material such as polyimide and/or an acrylic resin.

The light emitting diode De can be disposed on the overcoat layer 180. The light emitting diode De can include a first electrode 182, a second electrode 188 facing the first electrode 182 and an emissive layer 186 disposed between the first electrode 182 and the second electrode 188. One of the first electrode 182 and the second electrode 184 is an anode and the other of the first electrode 182 and the second electrode 184 can be a cathode. One of the first electrode 182 and the second electrode 184 is a reflective electrode and the other of the first electrode 182 and the second electrode 184 is a transmissive (or semi-transmissive) electrode.

The first electrode 182 on the overcoat layer 180 can be linked to the source electrode 170 through a contact hole of the overcoat layer 180 and the interlayer insulating layer 176. As an example, the first electrode 182 can be an anode with a multi-layered structure comprising a transparent conductive material and a non-transparent conductive material with high reflection efficiency.

For example, the transparent conductive material of the first electrode 182 can include a material with high work function value such as indium-tin-oxide (ITO) and/or indium-zinc-oxide (IZO), and the non-transparent conductive material of the first electrode 182 can include aluminum (Al), silver (Ag), copper (Cu), lead (Pb), molybdenum (Mo), titanium (Ti) and/or alloys thereof, but is not limited thereto.

In one embodiment, the first electrode 182 can have a laminated structure where a transparent conductive layer, a non-transparent conductive layer and a transparent conductive layer are sequentially disposed. In another embodiment, the first electrode 182 can have a laminated structure where a transparent conductive layer and a non-transparent conductive layer are sequentially disposed.

The first electrode 182 can be extended from the emission area EA to overlap with the second capacitor pattern 164. The second capacitor pattern 164, the interlayer insulating layer 176 and the first electrode 182 constitute a second capacitor pattern Cs2.

In this case, the first capacitor Cs1 can be connected parallel to the second capacitor Cs2 to form the storage capacitor Cst (FIG. 2).

A bank layer 184 covering an edgy of the first electrode 182 and having an opening corresponding to the emitting area EA can be disposed on the first electrode 182. The bank layer 184 can include a transparent material or a non-transparent material such as black material for blocking light interference between adjacent sub-pixels. For example, the bank layer 184 can include a light shielding material comprising at least one of an organic material or a color pigment, an organic black material or carbon. A spacer can be disposed on the bank layer.

The emissive layer 186 is disposed on the bank layer 184 and the first electrode 182 exposed by the opening of the bank layer 184. In one embodiment, the emissive layer 186 can include an emitting material layer. In another embodiment, the emissive layer 184 can be laminated with a hole layer, the emitting material layer and an electron layer in sequence or in reversely sequence.

For example, the emissive layer 186 can include a hole injection layer, a hole transport layer, the emitting material layer, an electron transport layer and an electron injection layer. Additionally or alternatively, the emissive layer 186 can further include an electron blocking layer disposed between the hole transport layer and the emitting material layer and/or a hole blocking layer disposed between the emitting material layer and the electron transport layer.

In one embodiment, the emitting material layer can include an organic luminescent material. The organic luminescent material can include a host and a dopant. The dopant can include at least one of a phosphorescent material, a fluorescent material and a delayed fluorescent material. The dopant can include at least one of a red dopant, a green dopant and a blue dopant.

In another embodiment, the emitting material layer can include inorganic luminescent particles. The inorganic luminescent particles can include at least one of quantum dots (QDs) and quantum rods (QRs).

The second electrode 188 is disposed on the emissive layer 186 over the entire surface of the substrate 150. As an example, the second electrode 188 can be a cathode comprising a transparent conductive material such as indium-tin-oxide (ITO) and/or indium-zinc-oxide (IZO), but is not limited thereto. In another example, the second electrode 188 can include a high reflective material such as aluminum (Al), magnesium (Mg), calcium (Ca), silver (Ag), alloys thereof and/or combinations thereof (for example, aluminum-magnesium alloy (AlMg)), but is not limited thereto.

The first electrode 182, the emissive layer 186 and the second electrode 188 constitute the light emitting diode De.

A first encapsulation layer 190 and a second encapsulation layer 192 are disposed sequentially on the second electrode 188 over the entire surface of the substrate 150 for blocking external oxygens and/or moistures from infiltrating to the light emitting diode De.

For example, the first encapsulation layer 190 can include a non-photosensitive organic or inorganic insulating material such as a acryl resin, an epoxy resin, a phenolic resin, a polyamide resin, a polyimide resin, a polyethylene resin and/or silicon oxy carbon (SiOC), and/or a photosensitive organic insulating material such as photo-acryl. The first encapsulation layer 190 can further comprise desiccant. The second encapsulation layer 192 can include metal or an inorganic material.

FIG. 4 illustrates a schematic diagram of a gate driving panel circuit and components of a non-display area in accordance with one embodiment of the present disclosure. FIG. 4 assumes that the second type of the first gate driving circuit GPC #1 is disposed in the gated driving panel circuit area GPCA.

With referring to FIG. 4, a first out but buffer block BUF #1, a first logic block LOGCI #1 and a first real-time sensing control block RT #1 can be disposed in the gate driving panel circuit area GPCA.

The first output buffer block BUF #1 can include a first scan output buffer SCBUF1 for outputting a first scan signal (SC1), a second scan output buffer SCBUF2 for outputting a second scan signal (SC2), a third scan output buffer SCBUF3 for outputting a third scan signal (SC3), and a fourth scan output buffer SCBUF4 for outputting a fourth scan signal (SC4).

The four scan output buffers SCBUF1, SCBUF2, SCBUF3 and SCBUF4 can include two top scan output buffers disposed on a central areal BDA and two bottom scan output buffers disposed under the central area BDA. For example, the top scan output buffers can be the first scan output buffer SCBUF1 and the second scan output buffer SCBUF2, and the bottom scan output buffers can be the third scan output buffer SCBUF3 and the fourth scan output buffer SCBUF4. In other words, both the first scan output buffer SCBUF1 and the second scan output buffer SCBUF2 can be located in a first direction based on the central area BDA, and both the third scan output buffer SCBUF3 and the third scan output buffer SCBUF4 can be located in a direction opposite to the first direction based on the central area BDA.

For example, the first scan output buffer SCBUF1 can include a first scan pull-up transistor T6sc1 and/or a first scan pull-down transistor T7sc1. The second scan output buffer SCBUF2 can include a second scan pull-up transistor T6sc2 and/or a second scan pull-down transistor T7sc2. The third scan output buffer SCBUF3 can include a third scan pull-up transistor T6sc3 and/or a third scan pull-down transistor T7sc3. The fourth scan output buffer SCBUF4 can include a fourth scan pull-up transistor T6sc4 and/or a fourth scan pull-down transistor T7sc4.

The top scan output buffers, first scan output buffer SCBUF1 and the second scan output buffer SCBUF2, and the bottom scan output buffers, the third scan output buffer SCBUF3 and the fourth scan output buffer SCBUF4, can have a symmetrical arrangement with respect to the central area BDA of the first output buffer block BUF #1.

The locations and/or shapes of the circuit components (T7sc1, T7sc2, T6sc1, T6sc2, etc.) included in each of the top scan output buffers SCBUF1 and SCBUF2 can be symmetrical to the locations and/or shape s of the circuit components (T7sc3, T7sc4, T6sc3, T6sc4, etc.) included in each of the bottom scan output buffers SCBUF3 and SCBUF4 based on the central areal BDA. The top scan output buffers SCBUF1 and SCBUF2 can have a left-right symmetrical structure. The bottom scan output buffers SCBUF3 and SCBUF4 can have a left-right symmetrical structure.

A clock signal line area CLA can be located in one side of the gate driving panel circuit area GPCA and can be an area where plural clock signal lines CLs. For example, the plural clock signal lines CLs can include plural scan clock signal lines CL_SCCLKs and plural carry clock signal lines CL_CRCLKs.

Each of the plural scan clock signal lines CL_SCCLKs and the plural carry clock signal lines CL_CRCLKs can have a multi-layered line structure so that the load for gate driving can be reduced.

The scan clock signal (SCCLK) can be more sensitive to signal delay or signal waveform changes in terms of driving than the carry clock signal (CRCLK). Therefore, the line width of each of the plural scan clock signal lines CL_SCCLKs can be designed to be wider than the line width of each of the plural carry clock signal lines CL_CRCLK so that the load on the plural scan clock signal lines CL_SCCLK can be reduced.

The plural scan clock signal lines CL_SCCLKs can be further away from the first gate driving panel circuit GPC #1 than the plural carry clock signal lines CL_CRCLK.

A first power line area PLA1 is located on a side of the gate driving panel circuit area GPCA, and can include a gate high-potential voltage line HVL arrange in a column direction.

For example, the gate high-potential voltage line HVL can include a first gate high-potential voltage line HVL1 for transmitting a first gate high-potential voltage GVDD1 to the first gate driving panel circuit GPC #1, a second gate high-potential voltage line HVL2 for transmitting a second gate high-potential voltage GVDD2 to the first gate driving panel circuit GPC #1, and a third gate high-potential voltage lien HVL3 for transmitting a third gate high-potential voltage GVDD3 to the first gate driving panel circuit GPC #1.

The first gate high-potential voltage line HVL1 can be a first gate high-potential node, or can be electrically connected to the first gate high-potential node. The second gate high-potential voltage line HVL2 can be a second gate high-potential node, or can be electrically connected to the second gate high-potential node. The third gate high-potential voltage line HVL3 can be a third gate high-potential node, or can be electrically connected to the third gate high-potential node.

The first gate high-potential voltage HVL1, the second gate high-potential voltage HVL2 and the third gate high-potential voltage HVL3 can be supplied to the first logic block LOGIC #1 included in the first gate driving panel circuit GPC #1.

Alternatively, the first gate high-potential voltage GVDD1 among the first gate high-potential voltage GVDD1, the second gate high-potential voltage GVDD2 and the third gate high-potential voltage GVDD3 can be supplied to the first real-time sensing control block RT #1 included in the first gate driving panel circuit GPC #1.

A second power line area PLA 2 can be located on the other side of the gate driving panel circuit area GPCA, and can include a gate low-potential voltage line LVL arranged in a column direction.

For example, the gate low-potential voltage line LVL can include a first gate low-potential voltage line LVL1 for transmitting a first gate low-potential voltage GVSS1 to the first gate driving panel circuit GPC #1, a second gate low-potential voltage line LVL2 for transmitting a second gate low-potential voltage GVSS2 to the first gate driving panel circuit GPC #1, and a third gate low-potential voltage lien LVL3 for transmitting a third gate low-potential voltage GVSS3 to the first gate driving panel circuit GPC #1.

The first gate low-potential voltage line LVL1 can be a first gate low-potential node, or can be electrically connected to the first gate low-potential node. The second gate low-potential voltage line LVL2 can be a second gate low-potential node, or can be electrically connected to the second gate low-potential node. The third gate low-potential voltage line LVL3 can be a third gate low-potential node, or can be electrically connected to the third gate low-potential node.

The first gate low-potential voltage GVSS1 can be supplied to the first to fourth scan output buffers SCBUF1, SCBUF2, SCBUF3 and SCBUF4 included in the first output buffer block BUF #1 of the first gate driving panel circuit GPC #1.

The first gate low-potential voltage GVSS1 can be applied into a drain node or a source node of the first to fourth scan pull-down transistors T7sc1, T7sc2, T7sc3 and T7sc4 each of which is included in the first to fourth scan output buffers SCBUF1, SCBUF2, SCBUF3 and SCBUF4, respectively.

To this end, the display device 100 can further include plural gate low-potential voltage connection lines LVL1_CP, LVL2_CP and LVL3_CP that connects the plural gate low-potential voltage lines LVL1, LVL2 and LVL3 disposed in the second power line area PLA2 to the first gate driving panel circuit GPC #1 disposed in the gated driving panel circuit area GPCA. The plural gate low-potential voltage connection lines LVL1_CP, LVL2_CP and LVL3_CP can be extended in a row direction and can be arranged in a direction parallel to the gate line GL (FIG. 2) of the display area AA. In one embodiment, the plural gate low-potential voltage connection lines LVL1_CP, LVL2_CP and LVL3_CP can pass though the central area BDA of the first output buffer block BUF #1.

The first gate low-potential voltage connection line LVL1_CP can be arranged to extend in a row direction so that the first gate low-potential voltage line LVL1 can be electrically connected to the drain node or the source node of the first and second scan pull-down transistors T7sc1 and T7sc2 included in the top scan output buffers SCBUF1 and SCBUF2. The first gate low-potential voltage connection line LVL1_CP can be arranged to extend in a row direction so that the first gate low-potential voltage line LVL1 can be electrically connected to the drain node or the source node of the third and fourth scan pull-down transistors T7sc3 and T7sc4 included in the bottom scan output buffers SCBUF3 and SCBUF4.

In one embodiment, the first gate low-potential voltage connection line LVL1_CP can pass through the central areal BDA between the top scan output buffers SCBUF1 and SCBUF2 and the bottom scan output buffers SCBUF3 and SCBUF4.

The second gate low-potential voltage GVSS2 can be supplied to the first logic block LOGIC #1 of the first gate driving panel circuit GPC #1. In one embodiment, the second gate low-potential voltage GVSS2 can be applied to a drain node or a source node of a first inverter control transistor T4q included in the first logic block LOGIC #1.

To this end, the second gate low-potential voltage connection line LVL2_CP can be arranged to extend in a row direction so that the second gate low-potential line LVL2 can be electrically connected to the drain node or the source node of the first inverter control transistor T4q included in the first logic block LOGIC #1.

In one embodiment, the second gate low-potential voltage connection line LVL2_CP can pass through the central areal BDA between the top scan output buffers SCBUF1 and SCBUF2 and the bottom scan output buffers SCBUF3 and SCBUF4.

The third gate low-potential voltage GVSS3 can be supplied to the first logic block LOGIC #1 of the first gate driving panel circuit GPC #1. In one embodiment, the third gate low-potential voltage GVSS3 can be applied to a drain node or a source node of holding transistors HTFTs that is included in the first logic block LOGIC #1 and is connected to a third gate low-potential node. In one embodiment, the holding transistors HTFTs can include a second Q node discharge transistor, a fourth Q node discharge transistor, a second stabilization transistor, a first QB node discharge transistor, a second QB node discharge transistor, a fourth QB node discharge transistor.

To this end, the third gate low-potential voltage connection line LVL3_CP can be arranged to extend in a row direction so that the third gate low-potential line LVL3 can be electrically connected to the drain node or the source node of the holding transistor HTFT that is included in the first logic block LOGIC #1 and is connected to a third gate low-potential node.

In another embodiment, the third gate low-potential voltage connection line LVL3_CP can connect the third gate low-potential voltage line LVL3 to a drain node or a source node of the carry pull-down transistors T7sc1, T7sc2, T7sc3 and T7sc4 include in a carry output buffer of the first output buffer block BUF #1.

In one embodiment, the third gate low-potential voltage connection line LVL3_CP can pass through the central areal BDA between the top scan output buffers SCBUF1 and SCBUF2 and the bottom scan output buffers SCBUF3 and SCBUF4.

The top scan output buffers SCBUF1 and SCBUF2 and the bottom scan output buffers SCBUF3 and SCBUF4 included in the first output buffer block BUF #1 have a symmetrical structure based on the central areal BDA. Therefore, it is possible to transmit or supply effectively the gate low-potential voltages GVSS1, GVSS2 and GVSS3.

The functions and structures of the first to third gate high-potential voltage lines HVL1, HVL2 and HVL3 and the first to third gate low-potential voltage lines LVL1, LVL2 and LVL3 will be described in more detail.

The first gate high-potential voltage GVDD1 transmitted through the first gate high-potential voltage line HVL1 can be a high-potential voltage supplied to a Q node charging block of the input/reset block and used when charging the Q node. For example, the first gate high-potential voltage GVDD1 transmitted through the first gate high-potential voltage line HVL1 can be a high-potential voltage connected to the drain node or the source node of the first Q node charging transistor and can be used in charging the Q node.

Alternatively, the first gate high-potential voltage GVDD1 transmitted through the first gate high-potential voltage line HVL1 can be a high-potential voltage supplied to the real-time sensing control block RT #1 and can be used in charge the Q node during the real-time sensing driving period.

The second high-potential voltage GVDD2 transmitted through the second gate high-potential voltage line HVL2 can be a high-potential voltage used in charging the QB node.

The third high-potential voltage GVDD3 transmitted through the third gate high-potential voltage line HVL3 can be applied to a drain node (or a source node) and a gate node of the first Q node charge control transistor, and can be applied to the Q node through the first Q node charge control transistor. The first Q node charge control transistor can act as compensating a negative threshold voltage of the first Q node charging transistor.

The first gate low-potential voltage GVSS1 transmitted through the first gate low-potential voltage line LVL1 can be supplied to the first to the fourth scan output buffers SCBUF1, SCBUF2, SCBUF3 and SCBUF4 of the first output buffer block BUF #1 so that the voltage levels of the first to fourth scan signals can be shifted to a turn-off voltage level and that the driving to the first to fourth scan signals can be turned off.

The second gate low-potential voltage GVSS2 transmitted through the second gate low-potential voltage line LVL2 can be a low-potential voltage that is applied to a drain node or a source node of the first inverter control transistor included in the inverter block. In one embodiment, the second gate low-potential voltage GVSS2 can be constituted with a separate low-potential voltage divided from the third gate low-potential voltage GVSS3.

The third gate low-potential voltage GVSS3 transmitted through the third gate low-potential voltage line LVL3 can be a low-potential voltage that is supplied to the first logic block LOGIC #1 and is used in discharging (or turning off) the Q node and the QB node. In one embodiment, the third gate low-potential voltage GVSS3 transmitted through the third gate low-potential voltage line LVL3 can be a power voltage supplied to the largest number of transistors.

The first gate high-potential voltage GVDD1, the second gate high-potential voltage GVDD2, the first gate low-potential voltage GVSS1, the second gate low-potential voltage GVSS2 and the third gate low-potential voltage GVSS3 can influence on the output of the first gate driving panel circuit GPC #1 directly.

Each of the first gate high-potential voltage line HVL1, the second gate high-potential voltage line HVL2, the first gate low-potential voltage line LVL1, the second gate low-potential voltage line LVL3 and the third gate low-potential voltage line LVL3 can have a multi-layered line structure because the smaller the line resistance, the better for each of the lines HVL1, HVL2, LVL1, LVL2 and LVL3.

The first Q node charge control transistor connected to the third gate high-potential voltage line HVL3 does not require high voltage. Additionally, there are many lines that intercross and overlap with the third gate high-potential voltage line HVL3. Because of those points, the third gate high-potential voltage line HVL3 can have a single-layered line structure.

A trench area OCTA can be disposed between the second power line area PLA2 and the first output buffer block BUF #1. In one embodiment, the emissive layer 186 (FIG. 3) in the display area AA can be arranged to extend to the non-display area NA.

The trench area OCTA can form a trench of the overcoat layer 180 and the bank layer 184 between the display area AA and the non-display area NA so that the organic material of the overcoat layer 180 and the bank layer 184 in the non-display area NA cannot be penetrate into external display area NA. When the trench area OCTA is adjacent to the display area AA, the emissive layer 186 is arranged in the trench area OCTA and therefore, external moisture can be penetrated into the emissive layer 186.

With referring to FIGS. 3 and 4, the second power line PLA 2 is disposed adjacently to the display area AA and the trench area OCTA is arranged spaced apart from the display area AA so that the emissive layer 186 cannot be arranged within the trench area OCTA. The trench area OCTA can be arranged on both sides of the display area AA. In one embodiment, the trench area OCTA can have one side of a straight shape in a plan view. In another embodiment, the trench area OCTA can have one side of an uneven or a concavo-convex shape in a plan view.

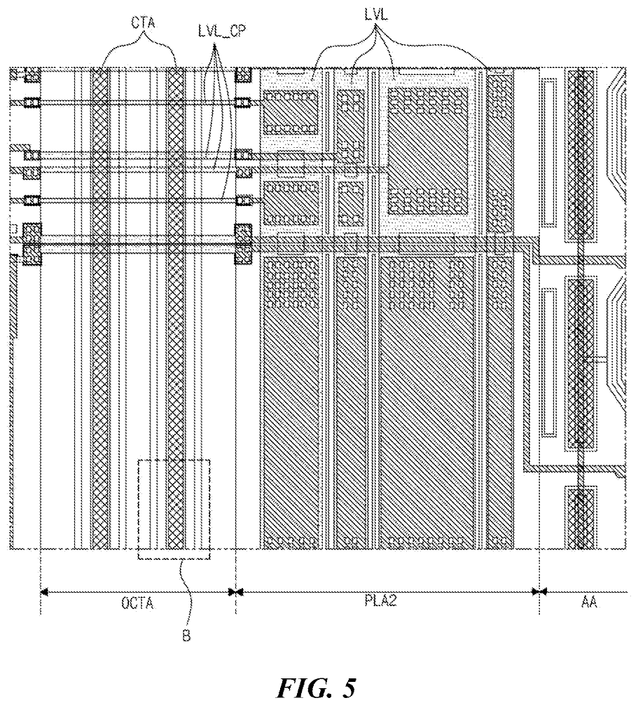

FIG. 5 illustrates a plan view enlarging a portion “A” of FIG. 4. With referring to FIG. 5, the display area AA can be arranged in one side of the second power line area PLA2 and the trench area OCTA can be arranged in the other side of the second power line area PLA2.

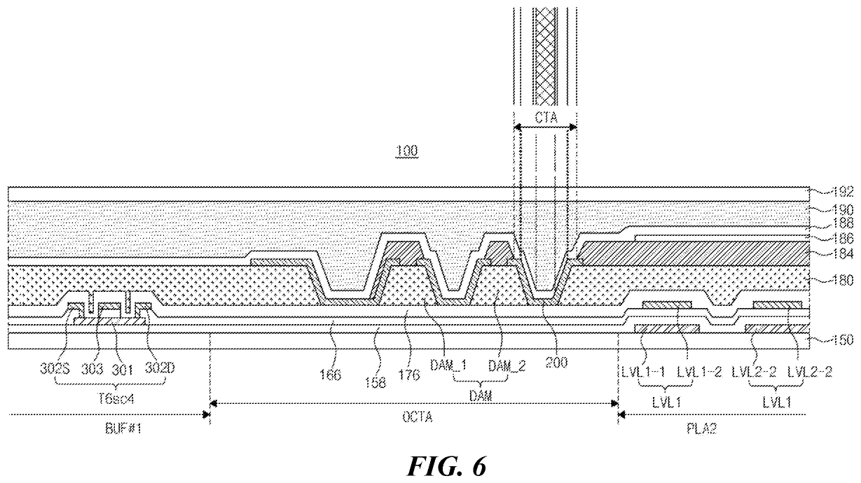

The gate low-potential voltage connection lines LVL1_CP, LVL2_CP and LVL3_CP can be arranged to extend to a row direction in the trench area OCTA. In addition, a contact portion CTA where a portion of the second electrode 188 (FIG. 6) and an auxiliary electrode 200 (FIG. 6) can be arranged in a column direction in the trench area OCTA.

In one embodiment, the gate low-potential voltage connection lines LVL1_CP, LVL2_CP and LVL3_CP can be disposed in the same layer and/or can include the same material as the light shield layer 152 (FIG. 3). The light shield layer 152 and the gate low-potential voltage connection lines LVL1_CP, LVL2_CP and LVL3_CP can be disposed on the substrate 150. The buffer layer 158 and the interlayer insulating layer 176 can be disposed on the light shield layer 152 and the gate low-potential voltage connection lines LVL1_CP, LVL2_CP and LVL3_CP.

At least one contact portion CTA can be disposed in the trench area OCTA. In one embodiment, two contact portions CTAs can be arranged in parallel.

FIG. 6 illustrate a cross-sectional view taken along a line VI-VI′ of FIG. 4 and enlarging a portion “B” of FIG. 5. When describing the components or elements of FIG. 6, the descriptions of the components that are the same as or corresponding to those of FIG. 3 will be omitted or simplified.

The first gate low-potential voltage line LVL1 and the second gate low-potential voltage line LVL2 are disposed on the substrate 150 in the non-display area NA.

In one embodiment, each of the first gate low-potential voltage line LVL1 and the second gate low-potential voltage line LVL2 can include a first layer LVL1-1 or LVL2-1 and a second layer LVL1-2 or LVL2-2. Each of the first layers LVL1-1 and LVL2-1 can be connected to each of the second layers LVL1-2 and LVL2-2, respectively, through the contact hole formed in the buffer layer 158 and the gate insulating layer 166 disposed on the first layer LVL1-1 or LVL2-1.

The buffer layer 158 disposed on the first layers LVL1-1 and LVL2-1 can be arranged to extend to the non-display area NA. In one embodiment, the fourth scan pull-up transistor T6sc4 in the fourth scan output buffer SCBUF4 on the buffer layer 158 in the first output buffer block BUF #1 area. An active layer 301 of the fourth scan pull-up transistor T6sc4 can be disposed on the buffer layer 158.

In one embodiment, the active layer 301 can include metal oxide, but is not limited thereto. In one embodiment, the active layer 301 can include at least one of indium-gallium-zinc-oxide (IGZO), indium-zinc-oxide (IZO), indium-gallium-tin-oxide (IGZO) and indium-gallium-oxide (IGO). In another embodiment, the active layer can include low temperature polycrystalline silicon (LTPS) semiconductor material, but is not limited thereto.

The gate insulating layer 166 can be disposed on the active layer 301. A source electrode 302S and a drain electrode 302D of the fourth scan pull-up transistor T6sc4 can be electrically connected to the active layer 301 through a hole in the gate insulating layer 166. A gate electrode 303 can be disposed on the gate insulating layer 166 correspondingly to a channel area of the active layer 301.

The second layers LVL1-2 and LVL2-2 of the first gate low-potential voltage line LVL1 and the second gate low-potential voltage line LVL2 can be disposed on the gate insulating layer 166 in the second power line area PLA2.

The source electrode 302S, the drain electrode 302D, the gate electrode 303 and the second layers LVL1-2 and LVL2-2 can be disposed in the same layer and/or can include the same material. The source electrode 302S, the drain electrode 302D, the gate electrode 303 can be disposed in the same layer and/or can include the same material as the source electrode 170, the drain electrode 172 and the gate electrode 168, respectively, of the driving thin film transistor Td (FIG. 3) in the sub-pixel S_PXL of the display area AA (FIG. 3).

The interlayer insulating layer 176 and the overcoat layer 180 can be disposed on the source electrode 302S, the drain electrode 302D, the gate electrode 303 and the second layers LVL1-2 and LVL2-2. The bank layer 184 can be disposed on the overcoat layer 180 in the second power line area PLA2 and a portion of the trench area OCTA. The overcoat layer 180 and the bank layer 184 can be removed in the trench area OCTA so that external moisture cannot penetrate therein.

In one embodiment, the overcoat layer 180 and the bank layer 184 can be completely removed from the entire trench area OCTA. In another embodiment, the trench area OCTA can include at least one dams DAM constituting with the overcoat layer 180 and the bank layer 184.

The at least one dams DAM can be extended in a row direction in the trench area OCTA. In one embodiment, plural dams DAMs can be displaced with regularly spaced apart from each other. In another embodiment, the plural dams can include a first dam DAM_1 and a second dam DAM_2. In this case, the second electrode 188 can be connected to the auxiliary electrode 200 in an area where no dam is disposed, and in an area between the first dam DAM1_1 and the second dam DAM_2 within the trench area OCTA.

The second electrode 188 is connected to the auxiliary electrode 200 so that the second electrode 188 can reduce its electrical resistance and the direct connection between two metal materials enables the external moisture to be blocked, and therefore to block moisture infiltration.

The contact portion CTA where the second electrode 188 is connected to the auxiliary electrode 200 can be disposed between the at least one dams DAM and the overcoat layer 180 disposed on both sides of the trench area OCTA.

The auxiliary electrode 200 can be formed with the same material and the same process as the first electrode 182. The auxiliary electrodes 200 can be disposed in a column direction with spaced apart from each other in the trench area OCTA. In one embodiment, the auxiliary electrode 200 can be disposed on the side and/or a portion of the top surface of the overcoat layer that constitutes the at least one dam DAMs.

In one embodiment, the bank layer 184 can be disposed on the at least one dam DAM and the auxiliary electrode 200 covering at least one dam DAM in the trench area OCTA. In another embodiment, the bank layer 184 constituting the at least one dam DAM can be disposed with covering the top surface and at least one side of the overcoat layer 180. In this case, the auxiliary electrode 200 can be disposed between the bank layer 184 and the overcoat layer 180 on the side of the overcoat layer 180.

The emissive layer 186 can be disposed in a portion of the second power line area PLA2. The second electrode 188 can be disposed on the emissive layer 186 in the second power line area PLA2, and on the bank layer 184 and the auxiliary electrode 200 in the trench area OCTA and on the overcoat layer 180 in the first output buffer block BUF #1. In one embodiment, the second electrode 188 can be disposed on the entire display area AA and can be extended to a portion of the non-display area NA. For example, the second electrode 188 can be disposed to extend to the gate driving panel circuit area GPCA (FIG. 4) and the first power line area PLA1 (FIG. 4).

The first encapsulation layer 190 and the second encapsulation layer 192 can be disposed sequentially on the second electrode 188 so that external oxygen species and/or moisture cannot be penetrated to the light emitting diode De (FIG. 3).

It will be apparent to those skilled in the art that various modifications and variations may be made in the present disclosure without departing from the scope of the disclosure. Thus, it is intended that the present disclosure cover the modifications and variations of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet, including but not limited to These and other changes can be made to the embodiments in light of the above-detailed description. In general, in the appended claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate including a display area and a non-display area;
a plurality of sub-pixels disposed in the display area;
at least one transistor disposed in the plurality sub-pixels;
an overcoat layer disposed on the at least one transistor; and
a light emitting diode disposed on the overcoat layer, the light emitting diode including:
a first electrode electrically connected to the at least one transistor;
a second electrode facing the first electrode; and
an emissive layer disposed between the first electrode and the second electrode,
at least one trench area in the non-display area;
an auxiliary electrode in the at least one trench area disposed in the non-display area;
wherein the overcoat layer and the second electrode extend to the non-display area, and
wherein at least a portion of the second electrode is electrically connected to the auxiliary electrode in at least one trench area disposed in the non-display area.

2. The display device of claim 1, further comprising a driving circuit and a power line disposed in the non-display area;
wherein the at least one trench area is disposed between the driving circuit and the power line.

3. The display device of claim 1, wherein the display device further comprises a bank layer disposed on the overcoat layer and overlapped to a portion of the first electrode in the display area, wherein the bank layer is extended to and disposed in the non-display area.

4. The display device of claim 2, wherein the display device further comprises a connection line extended in a row direction disposed in the at least one trench area, and wherein the link line is arranged parallel to a gate line in the display area.

5. The display device of claim 4, wherein the connection line is a gate low-potential voltage connection line and electrically connects the driving circuit to the power line, and
wherein the power line is a gate low-potential voltage line.

6. The display device of claim 3, wherein the display device further comprises at least one dam disposed in the at least one trench area.

7. The display device of claim 6, wherein the overcoat layer and the bank layer constitute the at least one dam.

8. The display device of claim 7, wherein at least a portion of the auxiliary electrode is disposed between the overcoat layer and the bank layer.

9. The display device of claim 8, wherein the second electrode is electrically connected to the auxiliary electrode among the at least one dam.

10. The display device of claim 1, wherein the auxiliary electrode comprises a same material as the first electrode in the display area.

11. The display device of claim 7, wherein the bank layer is disposed on the overcoat layer.

12. The display device of claim 7, wherein the bank layer is disposed on and at least one side of the overcoat layer.

13. The display device of claim 1, wherein the display device further comprises a light shield layer disposed under the at least one transistor.

14. The display device of claim 2, wherein the power line comprises a same material as the light shield layer.

15. The display device of claim 14, wherein the power line is disposed in a same layer as the light shield layer.

16. The display device of claim 1, wherein a side of the at least one trench area has a straight line from a plan view.

17. The display device of claim 1, wherein a side of the at least one trench has a concavo-convex shape from a plan view.

18. The display device of claim 1, wherein the emissive layer comprises an organic luminescent material.

19. The display device of claim 1, wherein the emissive layer comprises inorganic luminescent particles.

20. The display device of claim 5, wherein the gate low-potential voltage line is a multi-layered line structure.
